(19) United States
(12) Patent Application Publication
(10) Pub. No.: US 2026/0255836 A1
(43) Pub. Date: Aug. 27, 2026

(54) DISPLAY MODULE AND ELECTRONIC DEVICE INCLUDING THE DISPLAY MODULE

(71) Applicant: Samsung Display Co., Ltd., Yongin-Si (KR)

(72) Inventors: TAEMIN KIM, Yongin-si (KR); SUJI PARK, Yongin-si (KR); SEUNGHEE LEE, Yongin-si (KR)

(21) Appl. No.: 19/422,616

(22) Filed: Dec. 17, 2025

(30) Foreign Application Priority Data
Feb. 27, 2025 (KR) 10-2025-0025926
Apr. 21, 2025 (KR) 10-2025-0051700

(51) Int. Cl. H10K 59/38; G09G 3/00; G09G 3/3225; H10K 59/80

(52) U.S. Cl. CPC H10K 59/38; G09G 3/035; G09G 3/3225; H10K 59/873; G09G 2300/0408; G09G 2300/0804; G09G 2320/0242; G09G 2320/0666; G09G 2330/04

(57) ABSTRACT

A display module includes a base layer including first to third light emitting areas emitting different colors, and a non-light emitting area surrounding the first to third light emitting areas. A display element layer is disposed on the base layer and includes light emitting elements. A color filter layer is disposed on the display element layer and includes first to third color filters corresponding to the first to third light emitting areas, respectively. An overcoat layer is disposed on the color filter layer, and a brittleness index of the overcoat layer is about 0.03 or more and about 0.05 or less.

### CROSS-REFERENCE TO RELATED APPLICATIONS

This U.S. non-provisional patent application claims priority under 35 U.S.C. § 119 of Korean Patent Application Nos. 10-2025-0025926, filed on Feb. 27, 2025, and 10-2025-0051700, filed on Apr. 21, 2025, the entire contents of which are hereby incorporated by reference.

### BACKGROUND

The present disclosure herein relates to a display module and an electronic device including the same, and more particularly, to a display module with improved impact resistance and an electronic device including the same.

Various display modules for use in multimedia devices such as televisions, mobile phones, tablet computers, and game consoles are being developed. Meanwhile, research on thin display modules is being conducted to achieve various types of display panels, but thin display modules may have defects with reduced impact resistance.

### SUMMARY

Embodiments of the present disclosure may provide a display module with improved reliability by including an overcoat layer covering a color filter layer in the display module. Embodiments of the present disclosure may provide a display module with improved impact resistance by including an overcoat layer covering a color filter layer in the display module.

A display module according to an embodiment of the inventive concept includes a base layer including first to third light emitting areas emitting different colors, and a non-light emitting area surrounding the first to third light emitting areas, a display element layer disposed on the base layer and including light emitting elements, a color filter layer disposed on the display element layer and including first to third color filters corresponding to the first to third light emitting areas, respectively, and an overcoat layer disposed on the color filter layer, wherein a brittleness index of the overcoat layer is about 0.03 or more and about 0.05 or less.

In an embodiment, the overcoat layer may include a photocurable resin.

In an embodiment, a curing temperature of the photocurable resin may be about 50° C. or higher and about 85° C. or lower.

In an embodiment, the photocurable resin may include a resin selected from a siloxane-based resin, an acrylic resin, an epoxy-based resin, and a combination thereof.

In an embodiment, a thickness of the overcoat layer may be about 10 μm or more and about 20 μm or less.

In an embodiment, a hardness of the overcoat layer may be about 0.05 GPa or more and about 0.5 GPa or less.

In an embodiment, a modulus of the overcoat layer may be about 1 Gpa or more and about 10 Gpa or less.

In an embodiment, a refractive index of the overcoat layer may be about 1.5 or more and about 1.6 or less.

In an embodiment, a degree of planarization of the overcoat layer may be about 90% or more.

In an embodiment, the overcoat layer may have a light transmittance for visible light of about 99% or more.

In an embodiment, the color filter layer may further include a filter partition in which filter opening parts are defined, and the first to third color filters may be disposed within the filter opening parts in a one-to-one correspondence.

In an embodiment, the overcoat layer may be directly disposed on the filter partition and the first to third color filters.

In an embodiment, the first color filter may transmit red light, the second color filter may transmit green light, and the third color filter may transmit blue light.

In an embodiment, the display module may further include an input sensing layer disposed between the display element layer and the color filter layer, the input sensing layer may include a sensing insulation layer, a sensing metal layer disposed on the sensing insulation layer, and a passivation layer covering the sensing metal layer, and the color filter layer may be disposed directly on the passivation layer.

A display module according to an embodiment of the inventive concept includes a base layer, a display element layer disposed on the base layer and including light emitting elements, an input sensing layer disposed on the display element layer, a color filter layer disposed on the input sensing layer, and an overcoat layer disposed on the color filter layer, wherein a hardness of the overcoat layer is about 0.05 GPa or more and about 0.5 GPa or less, a modulus of the overcoat layer is about 1 Gpa or more and about 10 Gpa or less, and a brittleness index of the overcoat layer is about 0.03 or more and about 0.05 or less.

An electronic device according to an embodiment of the inventive concept includes a display device providing an image and including a display module, and a power module supplying power to the display device, wherein the display module includes a base layer including first to third light emitting areas emitting different colors, and a non-light emitting area surrounding the first to third light emitting areas, a display element layer disposed on the base layer and including light emitting elements, a color filter layer disposed on the display element layer and including first to third color filters corresponding to the first to third light emitting areas, respectively, and an overcoat layer disposed on the color filter layer, and a brittleness index of the overcoat layer is about 0.03 or more and about 0.05 or less.

In an embodiment, the electronic device may further include a window disposed on the display module, and a housing disposed below the display module and combined with the window to accommodate the display module.

In an embodiment, the electronic device may further include a processor and a memory.

### BRIEF DESCRIPTION OF THE FIGURES

The accompanying drawings are included to provide a further understanding of the inventive concept and are incorporated in and constitute a part of this specification. The drawings illustrate embodiments of the inventive concept and, together with the description, serve to explain principles of the inventive concept. In the drawings:

FIG. 1 is a block diagram of an electronic device according to an embodiment of the inventive concept;

FIG. 2 illustrates schematic diagrams of electronic devices according to embodiments of the inventive concept;

FIG. 3 is a perspective view of an electronic device according to an embodiment of the inventive concept;

FIG. 4 is an exploded perspective view of an electronic device according to an embodiment of the inventive concept;

FIG. 5 is a plan view of a display module according to an embodiment of the inventive concept;

FIG. 6 is a cross-sectional view of a display module according to an embodiment of the inventive concept; and

FIG. 7 is an enlarged cross-sectional view of a portion of a display module according to an embodiment of the inventive concept.

### DETAILED DESCRIPTION

The inventive concept may have various modifications and may be embodied in different forms, and example embodiments will be explained in detail with reference to the accompanying drawings. The inventive concept may, however, be embodied in different forms and should not be construed as limited to the embodiments set forth herein. Rather, all modifications, equivalents, and substituents which are included in the spirit and technical scope of the inventive concept should be included in the inventive concept.

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents.

It will be understood that, although the terms “first”, “second”, etc. may be used herein to describe various elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the inventive concept. Similarly, a second element, component, region, layer or section could be termed a first element, component, region, layer or section. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprise,” include,” and have” as well as variations such as “comprising,” “including,” having,” when used in this specification, specify the presence of stated features, numbers, steps, operations, elements, components or combinations thereof, but do not preclude the possibility of the presence or addition of one or more other features, numbers, steps, operations, elements, components, and combinations thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described with reference to the drawings.

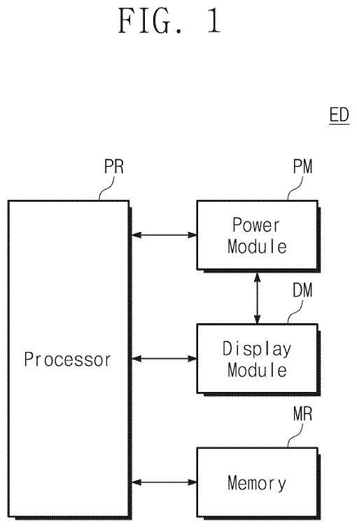

FIG. 1 is a block diagram of an electronic device according to an embodiment of the inventive concept. Referring to FIG. 1, an electronic device ED according to an embodiment may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), and a controller.

The memory MR may store data information necessary for the operation of the processor PR or the display module DM. When the processor PR executes an application stored in the memory MR, an image data signal and an input control signal may be transmitted to the display module DM, and the display module DM may process the received signal and output image information through a display screen. The display module DM may include a display panel that displays an image.

The power module PM may include a power supply module such as a power adapter or a battery device, and a power conversion module that converts power supplied by the power supply module to generate power required for the operation of the electronic device ED.

At least one of the components of the above-described electronic device ED may be included in the display module according to the embodiments described below and the display device of an embodiment including the same. In addition, some of the individual modules functionally included in one module may be included in the display device and others may be provided separately from the display device. For example, the display device may include the display module DM, and the processor PR, the memory MR, and the power module PM may be provided in the form of other devices within the electronic device ED other than the display device.

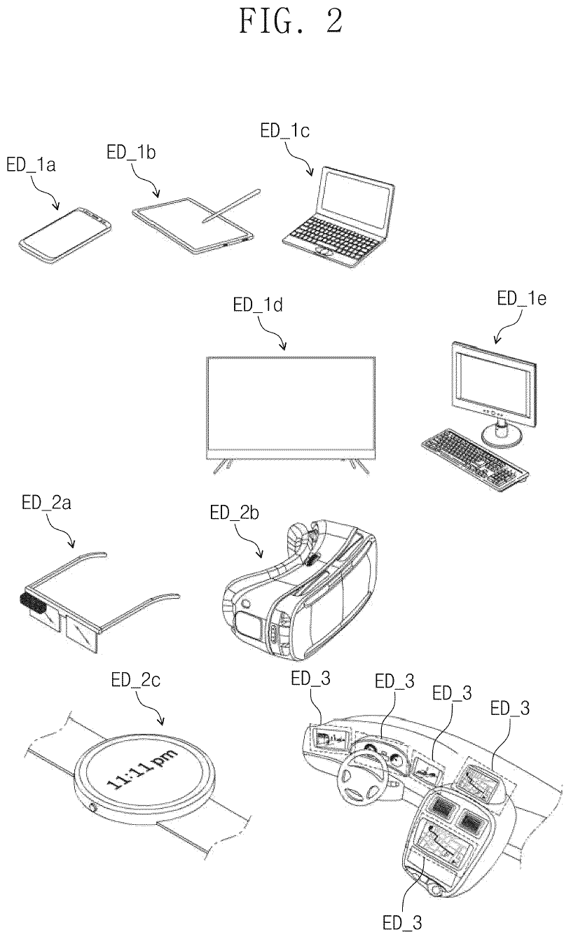

FIG. 2 illustrates schematic diagrams of embodiments of various electronic devices.

Referring to FIG. 2, various electronic devices including the display module according to an embodiment may include not only electronic devices for displaying images such as a smart phone ED_1a, a tablet PC ED_1b, a laptop ED_1c, a TV ED_1d, and a desk monitor ED_1e, but also wearable electronic devices such as smart glasses ED_2a, a head-mounted display ED_2b, and a smart watch ED_2c, and vehicle electronic devices ED_3 such as a dashboard of a car, center fascia, a Center Information Display (CID) disposed on a dashboard, and a room mirror display.

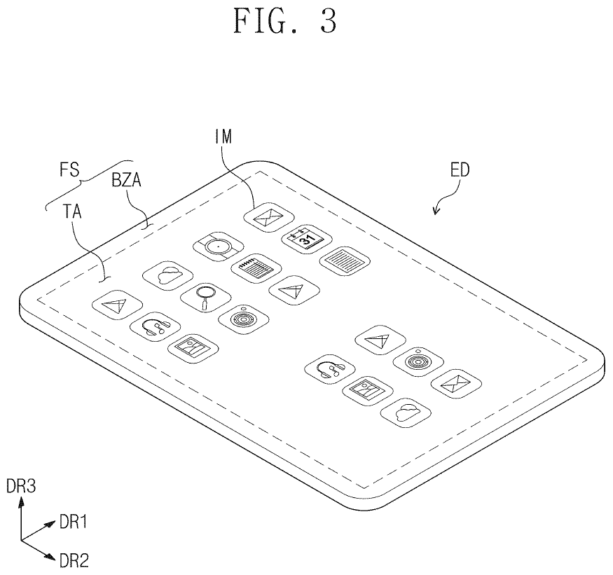

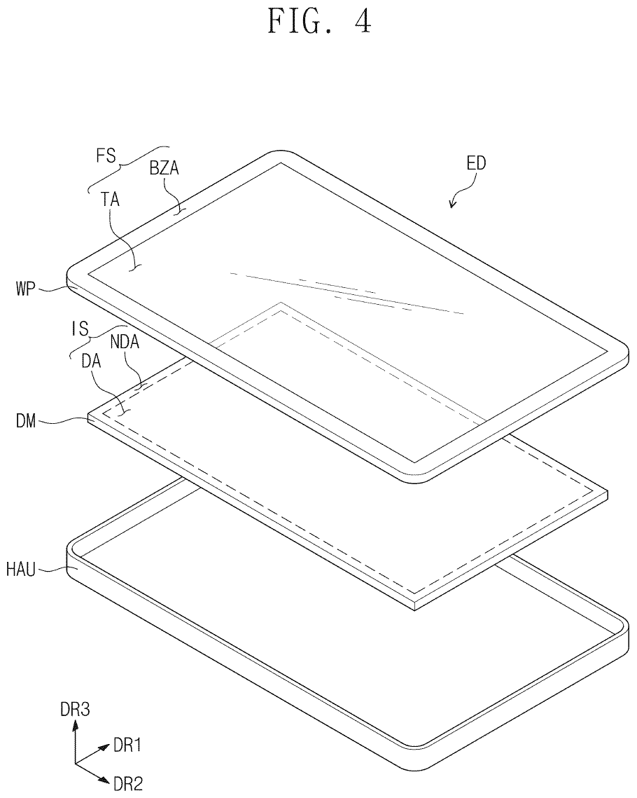

FIG. 3 is a perspective view of an electronic device according to an embodiment of the inventive concept. FIG. 4 is an exploded perspective view of an electronic device according to an embodiment of the inventive concept. FIG. 4 illustrates an exploded perspective view of the electronic device illustrated in FIG. 3. FIG. 3 and FIG. 4 illustrate an embodiment of any one among the electronic devices for displaying images such as a smartphone ED_1a, a tablet PC ED_1b, a laptop ED_1c, a TV ED_1d, and a desk monitor ED_1e, illustrated in FIG. 2, and is not limited to the illustrated form.

Referring to FIG. 3, in this embodiment, the electronic device ED may have a rectangular shape having short sides extending in a first direction DR1 and long sides extending in a second direction DR2 on a plane. However, an embodiment of the present invention is not limited thereto, and the electronic device ED may have various shapes such as a circle or a polygon.

The electronic device ED may display an image IM in a third direction DR3 through a display surface FS parallel to a plane defined by the first direction DR1 and the second direction DR2. The third direction DR3 may be substantially parallel to a normal direction of the display surface FS. The display surface FS on which the image IM is displayed may correspond to the front surface of the electronic device ED. The image IM may include a still image as well as a dynamic image. FIG. 3 illustrates icon images as an embodiment of the image IM.

In this embodiment, the front surface (or top) and back surface (or bottom) of each member or unit may be defined based on the direction in which the image IM is displayed. The front surface and back surface may be opposed to each other in the third direction DR3, and the normal direction of each of the front surface and back surface may be parallel to the third direction DR3. The distance between the front surface and back surface defined along the third direction DR3 may correspond to the thickness of the member (or unit).

In this specification, “on a plane” may be defined as a state viewed from the third direction DR3. In this specification, “on a cross-section” may be defined as a state viewed from the first direction DR1 or the second direction DR2. The directions indicated by the first to third directions DR1, DR2 and DR3 are relative concepts and may be converted into other directions.

The display surface FS on which the image IM is displayed in the electronic device ED may correspond to the front surface of the electronic device ED and may correspond to the display surface FS of the window WP (see FIG. 4). Hereinafter, the display surface, the front surface, and the front surface of the window WP of the electronic device ED will use the same reference symbol. Although not shown in the drawing, the electronic device ED may include a foldable display device including a folding area and a non-folding area, or a bending display device including at least one bending part.

Referring to FIG. 4, an electronic device ED according to an embodiment of the inventive concept may include a window WP, a display module DM, and a housing HAU.

The window WP may include an optically transparent insulating material. The window WP may include a transmissive area TA and a bezel area BZA. A user may view an image provided through the transmissive area TA corresponding to the display surface FS of the window WP.

The transmissive area TA may be an optically transparent area. The bezel area BZA may be an area having a relatively low light transmittance compared to the transmissive area TA. The bezel area BZA may have a certain color. The bezel area BZA may be adjacent to the transmissive area TA and may surround the transmissive area TA. The bezel area BZA may define the shape of the transmissive area TA. However, an embodiment of the inventive concept is not limited to what is shown, and the bezel area BZA may be disposed adjacent to only one side of the transmissive area TA, or a portion thereof may be omitted.

In FIGS. 3 and 4, the transmissive area TA is illustrated as a square shape. However, this is an illustration, and the transmissive area TA may have various shapes and is not limited to any one embodiment.

The display module DM may be disposed under the window WP. The display module DM may have a configuration that substantially generates an image IM. The image IM generated by the display module DM is displayed on the display surface IS and is externally recognized by the user through the transmissive area TA.

The display module DM includes a display area DA and a non-display area NDA. The display area DA may be an area activated according to an electrical signal. The non-display area NDA may be an area covered by the bezel area BZA. The non-display area NDA is adjacent to the display area DA. The non-display area NDA may surround the display area DA.

The housing HAU may accommodate the display module DM. The housing HAU may provide a base space in which the display module DM is disposed. The housing HAU may be disposed to cover the display module DM so that the top surface, which is the display surface IS of the electronic device ED, is exposed. The housing HAU may cover the side surface and the bottom surface of the display module DM and may expose the entire top surface. However, an embodiment of the inventive concept is not limited thereto, and the housing HAU may cover not only the side surface and the bottom surface of the display module DM but also a portion of the top surface.

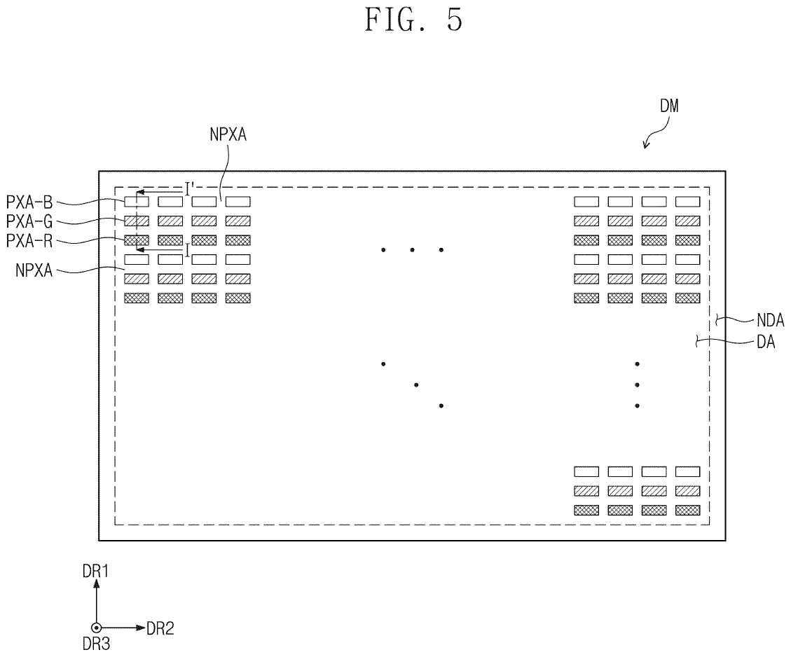

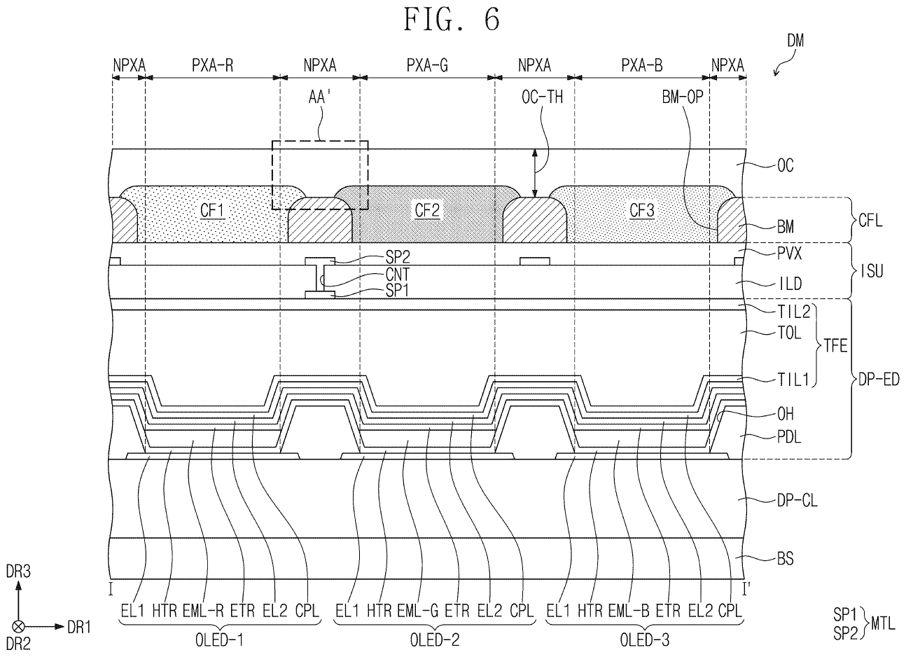

FIG. 5 is a plan view of a display module according to an embodiment of the inventive concept. FIG. 6 is a cross-sectional view of a display module according to an embodiment of the inventive concept. FIG. 6 illustrates a cross-section of an embodiment corresponding to cutting line I-I′ in FIG. 5.

Referring to FIGS. 5 and 6, a display module DM may include a display area DA and a non-display area NDA adjacent to the display area DA. The display area DA may include a first light emitting area, a second light emitting area, and a third light emitting area PXA-R, PXA-G, and PXA-B and a non-light emitting area NPXA.

The display area DA may include a non-light emitting area NPXA and light emitting areas PXA-R, PXA-G, and PXA-B. Each of the light emitting areas PXA-R, PXA-G, and PXA-B may be an area where light is generated from each of the light emitting elements OLED-1, OLED-2, and OLED-3. The light emitting areas PXA-R, PXA-G, and PXA-B may be spaced apart from each other on a plane.

Each of the light emitting areas PXA-R, PXA-G, and PXA-B may be an area separated by a pixel defining layer PDL. The non-light emitting area NPXA may be an area between neighboring light emitting areas PXA-R, PXA-G, and PXA-B and may be an area corresponding to the pixel defining layer PDL. Each of the light emitting areas PXA-R, PXA-G, and PXA-B in this specification may correspond to a pixel. The pixel defining layer PDL may distinguish the light emitting elements OLED-1, OLED-2, and OLED-3. Emission layers EML-R, EML-G, and EML-B of the light emitting elements OLED-1, OLED-2, and OLED-3 may be disposed in pixel opening parts OH defined in the pixel defining layer PDL.

Each of the light emitting elements OLED-1, OLED-2, and OLED-3 may include a first electrode EL1 (e.g., an anode) and a second electrode EL2 (e.g., a cathode) with each of the light emitting layers EML-R, EML-G, and EML-B disposed between a first electrode EL1 and a second electrode EL2. The second electrode EL2 may be a common electrode disposed over all of the light emitting layers EML-R, EML-G, and EML-B. Each of the light emitting elements OLED-1, OLED-2, and OLED-3 may include a hole control layer HTR between the first electrode EL1 and the light emitting layer as well as an electron control layer ETR between the light emitting element and the second electrode EL2. A capping layer CPL may disposed over the light emitting elements OLED-1, OLED-2, and OLED-3.

The light emitting areas PXA-R, PXA-G, and PXA-B may be classified into multiple groups according to the color of light generated from the light emitting elements OLED-1, OLED-2, and OLED-3. In the display module DM of an embodiment illustrated in FIGS. 5 and 6, three light emitting areas PXA-R, PXA-G, and PXA-B emitting red light, green light, and blue light are illustrated. For example, a display module DM of an embodiment may include a red light emitting area PXA-R, a green light emitting area PXA-G, and a blue light emitting area PXA-B, that are distinct from each other.

A plurality of light emitting elements OLED-1, OLED-2, and OLED-3 in the display module DM may emit light of different wavelength areas. For example, in an embodiment, the display module DM may include a first light emitting element OLED-1 that emits red light, a second light emitting element OLED-2 that emits green light, and a third light emitting element OLED-3 that emits blue light. That is, the red light emitting area PXA-R, the green light emitting area PXA-G, and the blue light emitting area PXA-B of the display module DM may correspond to the first light emitting element OLED-1, the second light emitting element OLED-2, and the third light emitting element OLED-3, respectively.

However, an embodiment of the inventive concept is not limited thereto, and the first to third light emitting elements OLED-1, OLED-2, and OLED-3 may emit light of the same wavelength range, or at least one may emit light of a different wavelength range. For example, the first to third light emitting elements OLED-1, OLED-2, and OLED-3 may all emit blue light.

The light emitting areas PXA-R, PXA-G, and PXA-B may be disposed in a stripe shape. Referring to FIG. 5, a plurality of red light emitting areas PXA-R, a plurality of green light emitting areas PXA-G, and a plurality of blue light emitting areas PXA-B may be arranged along the second direction axis DR2, respectively. In addition, the red light emitting areas PXA-R, the green light emitting areas PXA-G, and the blue light emitting areas PXA-B may be arranged alternately in that order along the first direction axis DR1.

In FIGS. 5 and 6, the areas of the light emitting areas PXA-R, PXA-G, and PXA-B are all illustrated as being similar, but an embodiment of the inventive concept is not limited thereto, and the areas of the light emitting areas PXA-R PXA-G, and PXA-B may differ from each other depending on the wavelength range of the light emitted. The areas of the light emitting areas PXA-R, PXA-G, and PXA-B may mean the areas when viewed on a plane defined by the first direction axis DR1 and the second direction axis DR2.

The arrangement form of the light emitting areas PXA-R, PXA-G, and PXA-B is not limited to that illustrated in FIG. 5, and the order in which the red light emitting areas PXA-R, the green light emitting areas PXA-G, and the blue light emitting areas PXA-B are arranged may be provided in various combinations depending on the characteristics of the display quality required from the display module DM. For example, the arrangement of the light emitting areas PXA-R, PXA-G, PXA-B may have a PENTILE™ arrangement or a Diamond Pixel™ arrangement.

In addition, the areas of the light emitting areas PXA-R, PXA-G, and PXA-B may be different from each other. For example, in an embodiment, the area of the green light emitting area PXA-G may be smaller than the area of the blue light emitting area PXA-B, but an embodiment of the inventive concept is not limited thereto.

The display module DM may include a base layer BS, a circuit element layer DP-CL disposed on the base layer BS, a display element layer DP-ED disposed on the circuit element layer DP-CL, an input sensing layer ISU disposed on the display element layer DP-ED, a color filter layer CFL disposed on the input sensing layer ISU, and an overcoat layer OC disposed on the color filter layer CFL.

The base layer BS may be a member that provides a base surface on which the circuit element layer DP-CL is disposed. The base layer BS may be a rigid substrate or a flexible substrate that may be bent, folded, rolled, or the like. The base layer BS may be an inorganic layer, an organic layer, or a composite material layer. The base layer BS may be a glass substrate, a metal substrate, a silicon substrate, a polymer substrate, or the like. For example, the base layer BS may be a glass substrate having a thickness of about 0.2 mm or less.

The circuit element layer DP-CL may be disposed on the base layer BS. The circuit element layer DP-CL may include an insulating layer, a semiconductor pattern, a conductive pattern, and a signal line. The insulating layer, the semiconductor layer, and the conductive layer may be formed on the base layer BS by a method such as coating, and deposition, and then the insulating layer, the semiconductor layer, and the conductive layer may be selectively patterned through multiple photolithography processes. After that, a semiconductor pattern, a conductive pattern, and a signal line included in the circuit element layer DP-CL may be formed.

The display element layer DP-ED may be disposed on the circuit element layer DP-CL. The display element layer DP-ED may include a pixel defining layer PDL in which a pixel opening part OH is defined, light emitting elements OLED-1, OLED-2, and OLED-3 disposed in the pixel opening part OH, and an encapsulation layer TFE disposed on the light emitting elements OLED-1, OLED-2, and OLED-3.

The light emitting elements OLED-1, OLED-2, and OLED-3 may include a first light emitting element OLED-1 emitting red light, a second light emitting element OLED-2 emitting green light, and a third light emitting element OLED-3 emitting blue light. The emission layers EML-R, EML-G, and EML-B of the light emitting elements OLED-1, OLED-2, and OLED-3 may be disposed and distinguished in pixel opening parts OH defined in the pixel defining layer PDL.

The encapsulation layer TFE may be disposed on the pixel defining layer PDL and the light emitting elements OLED-1, OLED-2, and OLED-3. The encapsulation layer TFE may seal the light emitting elements OLED-1, OLED-2, and OLED-3. The encapsulation layer TFE may have a function of protecting the light emitting elements OLED-1, OLED-2, and OLED-3 from moisture/oxygen and foreign substances.

The encapsulation layer TFE may include a first encapsulation inorganic layer TIL1, an organic layer TOL, and a second encapsulation inorganic layer TIL2. The first encapsulation inorganic layer TIL1 and the second encapsulation inorganic layer TIL2 protect the light emitting elements OLED-1, OLED-2, and OLED-3 from moisture/oxygen, and the organic layer TOL protects the light emitting elements OLED-1, OLED-2, and OLED-3 from foreign substances such as dust particles. The first encapsulation inorganic layer TIL1 and the second encapsulation inorganic layer TIL2 may include silicon nitride, silicon oxynitride, silicon oxide, titanium oxide, or aluminum oxide, but are not particularly limited thereto. The organic layer TOL may include an acrylic compound, an epoxy-based compound, or the like. The encapsulation organic layer may include a photopolymerizable organic material but is not particularly limited thereto.

The input sensing layer ISU may be disposed on the display element layer DP-ED. The input sensing layer ISU may have a function of detecting a user's touch and generating an electrical signal. The input sensing layer ISU may include a sensing insulation layer ILD, a passivation layer PVX disposed on the sensing insulation layer ILD, and a sensing metal layer MTL.

The sensing metal layer MTL may include a first metal pattern SP1 and a second metal pattern SP2. The first metal pattern SP1 and the second metal pattern SP2 may be connected through a contact hole CNT.

Each of the first metal pattern SP1 and the second metal pattern SP2 may have a single-layer structure or a multi-layer structure stacked along the third direction DR3. The conductive layer of the single-layer structure may include a metal layer or a transparent conductive layer. The metal layer may include molybdenum, silver, titanium, copper, aluminum, or an alloy thereof. The transparent conductive layer may include a transparent conductive oxide such as indium tin oxide, indium zinc oxide, zinc oxide, or indium zinc tin oxide. In addition, the transparent conductive layer may include a conductive polymer such as PEDOT, a metal nanowire, graphene, or the like. The conductive layer with a multi-layer structure may include metal layers. The metal layers may have a three-layer structure of, for example, titanium/aluminum/titanium. The conductive layer with a multi-layer structure may include at least one metal layer and at least one transparent conductive layer.

The sensing insulation layer ILD may be disposed between the first metal pattern SP1 and the second metal pattern SP2. The passivation layer PVX may be disposed on the sensing insulation layer ILD. The passivation layer PVX covers the second metal pattern SP2 and may reduce or eliminate the probability of damage occurring to the conductive pattern in a subsequent process.

Each of the sensing insulation layer ILD and the passivation layer PVX may include an inorganic film. The inorganic film may include at least one of aluminum oxide, titanium oxide, silicon oxide, silicon nitride, silicon oxynitride, zirconium oxide, or hafnium oxide.

Otherwise, each of the sensing insulation layer ILD and the passivation layer PVX may include an organic film. The organic film may include at least one of an acrylic resin, a methacrylic resin, a polyisoprene, a vinyl resin, an epoxy-based resin, a urethane-based resin, a cellulose-based resin, a siloxane-based resin, a polyimide-based resin, a polyamide-based resin, or a perylene-based resin.

The color filter layer CFL may be disposed on the input sensing layer ISU. The color filter layer CFL may be disposed directly on the passivation layer PVX. The color filter layer CFL may control the reflected light from the display module DM due to external light. Since the display module DM includes the color filter layer CFL, a separate polarizer may not be included.

The color filter layer CFL may include a filter partition BM in which filter opening parts BM-OP are defined, and a first color filter, a second color filter, and a third color filter CF1, CF2, and CF3 disposed in the filter opening parts BM-OP.

The color filter layer CFL may include color filters CF1, CF2, and CF3. The color filter layer CFL may include the first color filter CF1 as a red filter that transmits red light, the second color filter CF2 as a green filter that transmits green light, and the third color filter CF3 as a blue filter that transmits blue light. Each of the color filters CF1, CF2, and CF3 may include a polymer photosensitive resin and a pigment or dye. The first color filter CF1 may include a red pigment or dye, the second color filter CF2 may include a green pigment or dye, and the third color filter CF3 may include a blue pigment or dye. An embodiment of the inventive concept is not limited thereto, and the third color filter CF3 may not include a pigment or dye. The third color filter CF3 may include a polymer photosensitive resin and not include a pigment or dye. The third color filter CF3 may be transparent. The third color filter CF3 may be formed of a transparent photosensitive resin.

The filter partition BM may be disposed to overlap a second metal pattern SP2. The filter partition BM may prevent the reflection of external light by the second metal pattern SP2. The material constituting the filter partition BM is not particularly limited as long as it is a material that absorbs light. The filter partition BM is a layer having a black color, and in an embodiment of the inventive concept, the filter partition BM may include a black coloring agent. The black coloring agent may include a black dye or a black pigment. The black coloring agent may include carbon black, a metal such as chromium, or an oxide thereof.

A plurality of filter opening parts BM-OP may be defined in the filter partition BM. The filter opening parts BM-OP may overlap each other in a one-to-one correspondence with the light emitting elements OLED-1, OLED-2, and OLED-3. The filter opening part BM-OP may have a relatively large area on a plane compared to the corresponding pixel opening part OH. In an embodiment of the inventive concept, the filter partition BM may be omitted.

The overcoat layer OC may cover the filter partition BM and the color filters CF1, CF2, and CF3. The overcoat layer OC may be directly disposed on the color filter layer CFL to perform both the planarization function and the impact dissipation function. As the overcoat layer OC is disposed, a flat surface may be provided on the top surface of the display module DM.

The overcoat layer OC may include an organic material. The overcoat layer OC may include a photocurable resin. The overcoat layer OC may include any one of a siloxane-based resin, an acrylic-based resin, or an epoxy-based resin. The overcoat layer OC may include a polyhedral oligomeric silsesquioxane (POSS), a cyclic epoxy-based resin, or an acrylic resin. In this specification, the “~~-based” resin means one that includes a functional group of “~~.”

The overcoat layer OC may include a photocurable resin having a curing temperature of about 50° C. or more and about 85° C. or less. The overcoat layer OC is derived from a photocurable resin composition, and since the temperature at which the photocurable resin composition is cured is about 85° C. or lower, deterioration of the light emitting elements OLED-1, OLED-2, and OLED-3 may be prevented during the manufacture of the display module DM.

The thickness OC-TH of the overcoat layer OC may be about 5 μm or more and about 80 μm or less. For example, the thickness OC-TH of the overcoat layer OC may be about m or more and about 20 μm or less. The overcoat layer OC may be provided as a single layer having a thickness of about 5 μm or more and about 80 μm or less. Even if the overcoat layer OC has a thickness of about 5 μm or more and about 80 μm or less, sufficient impact resistance characteristics may be secured, since a brittleness index is about 0.03 or more and about 0.05 or less as described below.

The overcoat layer OC may have a light transmittance for visible light of about 99% or more. The refractive index of the overcoat layer OC may be about 1.5 or more and about 1.6 or less. In this specification, the refractive index of a specific layer may mean “the refractive index of a specific layer for light of about 750 nm wavelength.”

The brittleness index (BI) of the overcoat layer OC may be about 0.03 or more and about 0.05 or less. Since the overcoat layer OC includes an organic layer of the photocurable resin described above, the brittleness index may be about 0.03 or more and about 0.05 or less.

In this specification, the brittleness index may be calculated by Mathematical Equation 1 below.

$$BI = \frac{H}{E} \qquad [ Mathematical Equation 1 ]$$

In Mathematical Equation 1 above, BI means a brittleness index, H means a hardness, and E means Young's modulus.

The hardness of the overcoat layer OC may be about 0.05 GPa or more and about 0.5 GPa or less. For example, the hardness of the overcoat layer OC may be about 0.1 GPa or more and about 0.3 GPa or less. The Young's modulus of the overcoat layer OC may be about 1 GPa or more and about 10 GPa or less. For example, the Young's modulus of the overcoat layer OC may be about 3 GPa or more and about 7 GPa or less.

Hereinafter, the characteristic evaluation results of the display module according to an embodiment of the inventive concept will be described with reference to examples, comparative examples, and the above-described FIG. 6. In addition, the examples shown below are illustrations to help the understanding of the inventive concept, and the scope of the inventive concept is not limited thereto.

### (Manufacture of Display Module)

Each of Example 1, Example 2, and Comparative Examples 1 to 3 was manufactured through the stacked structure of the display module DM illustrated in FIG. 6. As shown in Table 1 below, each of the Examples and Comparative Examples was manufactured through the same manufacturing process except for the characteristics of the overcoat layer OC included in each of the Examples and Comparative Examples.

### (Evaluation of Display Module)

The evaluation values for each of Example 1, Example 2, and Comparative Examples 1 to 3 are shown in Table 1 below. In Table 1 below, the brittleness index (BI) represents a value calculated according to Mathematical Equation 1 after measuring the hardness and Young's modulus. In the case of crack occurrence in Table 1 below, an experiment was conducted by dropping a pen in the opposite direction of the third direction DR3 at a certain distance from the top surface of the display module DM of each of the Examples and Comparative Examples, that is, the top surface of the overcoat layer OC, and then observing same with a visual microscope, a reflection microscope, and a driving microscope, respectively, if a crack occurred in the overcoat layer OC, it was marked as O, and if no crack occurred, it was marked as X.

TABLE 1

| | | | | | Comparative | | Comparative | | Comparative | |
|---|---|---|---|---|---|---|---|---|---|---|
| | Example 1 | | Example 2 | | Example 1 | | Example 2 | | Example 3 | |
| Brittleness index (BI) | 0.03 | | 0.05 | | 0.09 | | 0.06 | | 0.02 | |
| Hardness | 0.1 | GPa | 0.25 | GPa | 0.44 | GPa | 0.39 | GPa | 0.01 | GPa |
| Young's modulus | 3 | GPa | 5 | GPa | 4.9 | GPa | 6.4 | GPa | 0.6 | GPa |

| | | | | | |
|---|---|---|---|---|---|
| Crack occurrence | X | X | ◯ | ◯ | ◯ |

Referring to Table 1 above, it can be confirmed that the display module according to an embodiment of the inventive concept has excellent impact resistance characteristics, as shown from the fact that the crack occurrence by crack evaluation is low compared to the Comparative Examples. Referring to Examples 1 and 2 and Comparative Examples 1 and 2, it can be confirmed that the impact resistance characteristics are deteriorated when the overcoat layer having a brittleness index exceeding about 0.05 is included. It is understood that the impact dispersion decreases, and the impact resistance characteristics are deteriorated when the overcoat layer having a brittleness index exceeding about 0.05 is included.

Referring to Examples 1 and 2 and Comparative Example 3, it can be confirmed that the impact resistance characteristics are deteriorated when the overcoat layer having a brittleness index less than about 0.03 is included. It is understood that the crack resistance is reduced, and the impact resistance characteristics are deteriorated when the overcoat layer having a brittleness index less than about 0.03 is included.

When manufacturing or using a display module, at least some of the components included in the display module may be cracked due to an external impact, and in particular, when an encapsulation layer covering a light emitting element is lifted due to a crack in the overcoat layer, the display characteristics of the display module may be deteriorated due to the occurrence of dark spots. Since the display module according to an embodiment of the inventive concept includes an overcoat layer having a brittleness index of about 0.03 or more and about 0.05 or less, a display module having improved display characteristics may be provided.

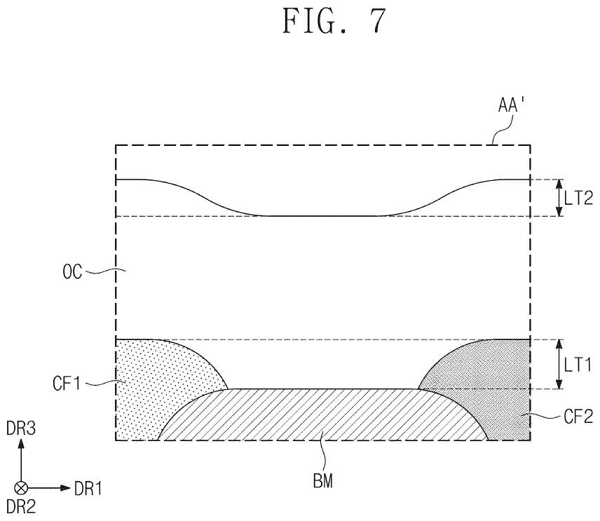

FIG. 7 is an enlarged cross-sectional view of a portion of a display module according to an embodiment of the inventive concept. FIG. 7 is an enlarged view of area AA′ illustrated in FIG. 6. Hereinafter, the degree of planarization characteristics of the overcoat layer OC will be described with reference to FIG. 7. For convenience of explanation, a step occurring in the overcoat layer OC is exaggerated in FIG. 7.

The overcoat layer OC included in the display module DM according to an embodiment of the inventive concept may have a degree of planarization (DOP) of about 90% or more. The degree of planarization of the overcoat layer OC may be about 90% or more and about 100% or less. Since the overcoat layer OC includes an organic layer of the photocurable resin described above, the degree of planarization may be about 90% or more and about 100% or less.

In this specification, the degree of planarization (X) may be calculated by Mathematical Equation 2 below.

$$X ( \% ) = \frac{LT 1 - LT 2}{LT 1} \times 100 \qquad [ Mathematical Equation 2 ]$$

In Mathematical Equation 2, X means a degree of planarization, LT1 means a first step LT1, and LT2 means a second step LT2. The first step LT1 may be defined as the maximum step that the top surface of the color filter CFL (see FIG. 6) has with respect to the third direction DR3. The second step LT2 may be defined as the maximum step that the top surface of the overcoat layer OC has in the direction parallel to the third direction DR3.

The display module according to an embodiment of the inventive concept includes an overcoat layer having a brittleness index of about 0.03 or more and about 0.05 or less and a degree of planarization of about 90% or more, thereby securing impact resistance and planarization characteristics and improving display characteristics. The electronic device according to an embodiment of the inventive concept may improve reliability by including the display module with improved display characteristics.

According to the present disclosure, a display module with improved impact resistance may be provided.

According to the present disclosure, an electronic device including a display module with improved impact resistance may be provided.

Although the present invention has been described above with reference to preferred embodiments thereof, it will be understood that those skilled in the art or having ordinary knowledge in the art can modify and change the present invention in various ways without departing from the spirit and technical scope of the present invention as described in the claims below.

Therefore, the technical scope of the present invention should not be limited to the contents described in the detailed description of the specification but should be determined by the claims.

What is claimed is:

1. A display module comprising:
a base layer comprising first to third light emitting areas emitting different colors, and a non-light emitting area surrounding the first to third light emitting areas;
a display element layer disposed on the base layer and comprising light emitting elements;
a color filter layer disposed on the display element layer and comprising first to third color filters corresponding to the first to third light emitting areas, respectively; and
an overcoat layer disposed on the color filter layer,
wherein a brittleness index of the overcoat layer is about 0.03 or more and about 0.05 or less.

2. The display module of claim 1, wherein the overcoat layer comprises a photocurable resin.

3. The display module of claim 2, wherein a curing temperature of the photocurable resin is about 50° C. or higher and about 85° C. or lower.

4. The display module of claim 2, wherein the photocurable resin includes a resin selected from a siloxane-based resin, an acrylic resin, an epoxy-based resin and a combination thereof.

5. The display module of claim 1, wherein a thickness of the overcoat layer is about 10 μm or more and about 20 μm or less.

6. The display module of claim 1, wherein a hardness of the overcoat layer is about 0.05 GPa or more and about 0.5 GPa or less.

7. The display module of claim 1, wherein a modulus of the overcoat layer is about 1 Gpa or more and about 10 Gpa or less.

8. The display module of claim 1, wherein a refractive index of the overcoat layer is about 1.5 or more and about 1.6 or less.

9. The display module of claim 1, wherein a degree of planarization of the overcoat layer is about 90% or more.

10. The display module of claim 1, wherein the overcoat layer has a light transmittance for visible light of about 99% or more.

11. The display module of claim 1,
wherein the color filter layer further comprises a filter partition in which filter opening parts are defined, and
the first to third color filters are disposed within the filter opening parts in a one-to-one correspondence.

12. The display module of claim 11, wherein the overcoat layer is directly disposed on the filter partition and the first to third color filters.

13. The display module of claim 1,
wherein the first color filter transmits red light,
the second color filter transmits green light, and
the third color filter transmits blue light.

14. The display module of claim 1,
wherein the display module further comprises an input sensing layer disposed between the display element layer and the color filter layer,
the input sensing layer comprises a sensing insulation layer, a sensing metal layer disposed on the sensing insulation layer, and a passivation layer covering the sensing metal layer, and
the color filter layer is disposed directly on the passivation layer.

15. A display module comprising:
a base layer;
a display element layer disposed on the base layer and comprising light emitting elements;
an input sensing layer disposed on the display element layer;
a color filter layer disposed on the input sensing layer; and
an overcoat layer disposed on the color filter layer,
wherein a hardness of the overcoat layer is about 0.05 GPa or more and about 0.5 GPa or less,
a modulus of the overcoat layer is about 1 Gpa or more and about 10 Gpa or less, and
a brittleness index of the overcoat layer is about 0.03 or more and about 0.05 or less.

16. The display module of claim 15, wherein a thickness of the overcoat layer is about 10 μm or more and about 20 μm or less.

17. The display device of claim 15,
wherein the overcoat layer is derived from a photocurable resin,
a curing temperature of the photocurable resin is about 50° C. or more and about 85° C. or less, and
the photocurable resin includes a resin selected from a siloxane-based resin, an acrylic resin, an epoxy-based resin, and a combination thereof.

18. An electronic device comprising:
a display device providing an image and comprising a display module; and
a power module supplying power to the display device,
wherein the display module comprises:
a base layer comprising first to third light emitting areas emitting different colors, and a non-light emitting area surrounding the first to third light emitting areas;
a display element layer disposed on the base layer and comprising light emitting elements;
a color filter layer disposed on the display element layer and comprising first to third color filters corresponding to the first to third light emitting areas, respectively; and
an overcoat layer disposed on the color filter layer, and
a brittleness index of the overcoat layer is about 0.03 or more and about 0.05 or less.

19. The electronic device of claim 18, further comprising:
a window disposed on the display module, and
a housing disposed below the display module and combined with the window to accommodate the display module.

20. The electronic device of claim 18, further comprising a processor and a memory.
